(19) United States
(12) Patent Application Publication
(10) Pub. No.: US 2004/0178516 A1
(43) Pub. Date: Sep. 16, 2004

(54) Semiconductor device

(75) Inventor: Tamotsu Ogata, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/646,840

(22) Filed: Aug. 25, 2003

(30) Foreign Application Priority Data
Mar. 12, 2003 (JP) 2003-066122(P)

(51) Int. Cl. H01L 27/11

(52) U.S. Cl. 257/903

(57) ABSTRACT

An interlayer dielectric film is formed to cover a gate electrode part formed on the surface of a semiconductor substrate. A shared contact hole exposing both of the upper surface of the gate electrode part and the surface of a cobalt silicide film is formed in the interlayer dielectric film. A side wall nitride film is formed on the side surface of the shared contact hole. On the surface of a lower portion of a side wall insulator film located on the bottom of the shared contact hole, a side wall nitride film is formed to cover the surface of a portion of a region of the semiconductor substrate located under the side wall insulator film. A barrier metal layer and a plug are formed in the shared contact hole. Thus, a semiconductor device suppressing a leakage current is obtained.

### BACKGROUND OF THE INVENTION

1. Field of the Invention

The present invention relates to a semiconductor device, and more particularly, it relates to a semiconductor device comprising a static memory cell.

2. Description of the Background Art

In a semiconductor device, a contact hole is formed in an insulator film for electrically connecting an element such as a transistor formed on the surface of a semiconductor substrate with a wire or another element formed on the insulator film covering the element. A prescribed plug or the like is formed in the contact hole for connecting the element with the wire or the like.

A semiconductor device described in Japanese Patent Laying-Open No. 11-168199 (1999) is described as an exemplary conventional semiconductor device having such a contact hole.

First, an element forming region is formed on the main surface of a semiconductor substrate. A gate electrode part of a transistor is formed on the element forming region through a gate insulator film. The gate electrode part is employed as a mask for implanting ions of an impurity having a prescribed conductivity type into the surface of the element forming region, thereby forming a pair of impurity regions defining source/drain regions. Thus formed is a transistor including the gate electrode part and the pair of source/drain regions.

An interlayer dielectric film consisting of a silicon oxide film is formed on the semiconductor substrate to cover the transistor. A bit line electrically connected with the first one of the pair of impurity regions is formed on the interlayer dielectric film. Another silicon oxide film is formed on the interlayer dielectric film to cover the bit line.

Then, a silicon nitride film is formed on the silicon oxide film. A resist mask is formed on the silicon nitride film. Dry etching is performed on the silicon nitride film, the silicon oxide film and the interlayer dielectric film through the resist mask, thereby forming a contact hole exposing the second one of the pair of impurity regions. Thereafter the resist mask is removed.

Then, still another silicon oxide film having a prescribed thickness is formed on the surface of the silicon nitride film including the inner surface of the contact hole. Anisotropic etching is performed on the silicon oxide film, thereby forming a side wall oxide film while partially leaving the silicon oxide film only on the side surface of the contact hole.

Thereafter a storage node of a polysilicon film having a prescribed conductivity type is formed on the silicon nitride film including the inner surface of the contact hole. This storage node is electrically connected with the second one of the impurity regions through the contact hole.

When the gate electrode part or the bit line is partially exposed on the side surface of the contact hole due to misregistration, for example, in formation of the contact hole in the aforementioned semiconductor device, the side wall oxide film covers the exposed portion.

Thus, the storage node and the gate electrode part or the storage node and the bit line are inhibited from an electrical short circuit.

A general semiconductor device may be provided with a shared contact hole exposing both of the surface of an impurity region (the surface of a semiconductor substrate) and a gate electrode part therein and electrically connecting the impurity region and the gate electrode part with each other through a plug or the like formed in the shared contact hole.

The shared contact hole is so formed as to continuously expose the gate electrode part and the impurity region located in the vicinity of the gate electrode part. In order to form a side wall oxide film on this shared contact hole, anisotropic etching is performed on a silicon oxide film similarly to the case of the aforementioned semiconductor device.

If the silicon oxide film is excessively etched, however, a portion of the side wall oxide film located in the vicinity of a surface portion of the semiconductor substrate located under the gate electrode part is reduced in thickness. Thus, an essentially unexposed surface portion of the semiconductor substrate is readily exposed.

If a side wall insulator film is previously formed on the side surface of the gate electrode part, the thickness of the side wall insulator film may also be reduced to partially expose the surface of the semiconductor substrate.

Thus, there is an apprehension that a current leaks from the gate electrode part or the impurity region to a region of the semiconductor substrate through the plug formed in the shared contact hole. Consequently, the semiconductor device is disadvantageously inhibited from a desired operation.

### SUMMARY OF THE INVENTION

The present invention has been proposed in order to solve the aforementioned problem, and an object thereof is to provide a semiconductor device capable of suppressing a leakage current.

The semiconductor device according to the present invention has a static memory cell including a pair of driver transistors having gates and drains cross-coupled with each other, a pair of access transistors having sources connected to the drains of the driver transistors respectively and a pair of load transistors having drains and gates connected to the drains of the driver transistors and the gates of the driver transistors respectively, and comprises a first gate electrode part, a second gate electrode part, a first impurity region of a prescribed conductivity type, a second impurity region of the prescribed conductivity type, an interlayer dielectric film, a first opening, a first gate side wall insulator film, a first opening side wall insulator film, a second gate side wall insulator film and a first conductor part. The first gate electrode part and the second gate electrode part are formed at a space from each other across an element forming region formed on the main surface of a semiconductor substrate. The first impurity region of the prescribed conductivity type is formed on a portion of the element forming region held between the first gate electrode part and the second gate electrode part. The second impurity region of the prescribed conductivity type is formed on another potion of the element forming region located opposite to the side provided with the second gate electrode part with respect to the first gate electrode part. The interlayer dielectric film is formed on the semiconductor substrate to cover the first gate electrode part and the second gate electrode part. The first opening is formed in the interlayer dielectric film to continuously expose the upper surface of the second gate electrode part and the surface of the first impurity region. The first gate side wall insulator film is formed on the side surface of the second gate electrode part. The first opening side wall insulator film is formed on the side surface of the first opening. The second gate side wall insulator film is formed on the surface of the first side wall insulator film to cover the surface of a portion of a region of the semiconductor substrate located under the first gate side wall insulator film. The first conductor part is formed to fill up the first opening for electrically connecting the first impurity region and the second gate electrode part with each other. The first one of the pair of load transistors includes the first gate electrode part, the first impurity region and the second impurity region. The second gate electrode part forming the gate of the second one of the pair of load transistors and the first impurity region of the first load transistor are electrically connected with each other through the first conductor part.

When the first gate side wall insulator film is reduced in thickness due to working for forming the first opening to expose a surface portion of the semiconductor substrate, the second gate side wall insulator film covers the exposed surface portion in the semiconductor device according to the present invention. Consequently, a current can be inhibited from leaking from the first conductor part toward the semiconductor substrate, and a stable operation of the semiconductor device can be ensured.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 illustrates an equivalent circuit of a static memory cell in a semiconductor device according to an embodiment of the present invention;

FIG. 2 is a plan view of the semiconductor device according to the embodiment shown in FIG. 1;

FIG. 3 is a sectional view of the semiconductor device according to the embodiment taken along the line III-III in FIG. 2;

FIG. 4 is a sectional view showing a step in a method of fabricating the semiconductor device according to the embodiment;

FIG. 5 is a sectional view showing a step carried out after the step shown in FIG. 4 in the method of fabricating the semiconductor device according to the embodiment;

FIG. 6 is a sectional view showing a step carried out after the step shown in FIG. 5 in the method of fabricating the semiconductor device according to the embodiment;

FIG. 7 is a sectional view showing a step carried out after the step shown in FIG. 6 in the method of fabricating the semiconductor device according to the embodiment;

FIG. 8 is a sectional view showing a step carried out after the step shown in FIG. 7 in the method of fabricating the semiconductor device according to the embodiment;

FIG. 9 is a sectional view showing a step carried out after the step shown in FIG. 8 in the method of fabricating the semiconductor device according to the embodiment;

FIG. 10 is a sectional view showing a step carried out after the step shown in FIG. 9 in the method of fabricating the semiconductor device according to the embodiment;

FIG. 11 is a sectional view showing a step carried out after the step shown in FIG. 10 in the method of fabricating the semiconductor device according to the embodiment;

FIG. 12 is a first partially fragmented sectional view for illustrating an effect of the semiconductor device according to the embodiment;

FIG. 13 is a first comparative partially fragmented sectional view for illustrating the effect of the semiconductor device according to the embodiment;

FIG. 14 is a second comparative partially fragmented sectional view for illustrating the effect of the semiconductor device according to the embodiment; and

FIG. 15 is a second partially fragmented sectional view for illustrating the effect of the semiconductor device according to the embodiment.

### DESCRIPTION OF THE PREFERRED EMBODIMENTS

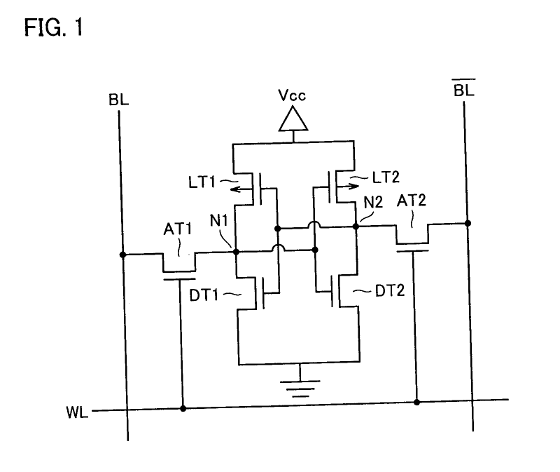

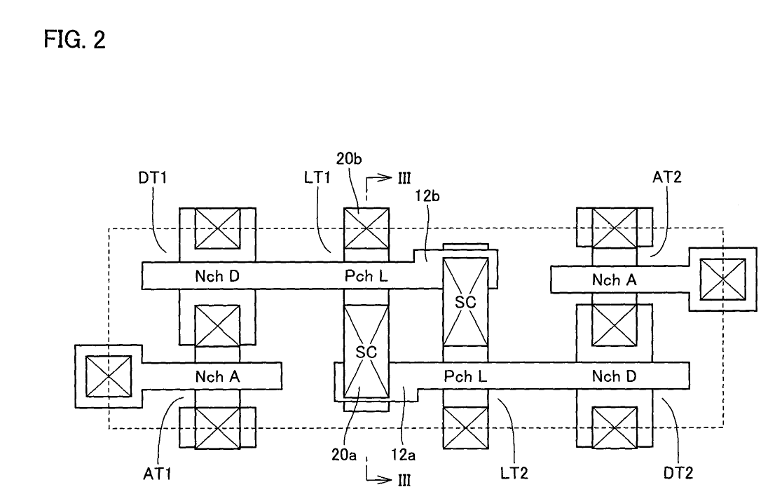

A semiconductor device comprising a static memory cell is now described as a semiconductor device according to an embodiment of the present invention. FIGS. 1 and 2 show an equivalent circuit of the static memory cell and the planar structure thereof respectively.

As shown in FIGS. 1 and 2, a memory cell is arranged on the intersection between a complementary data line (bit line) BL and a word line WL arranged in the form of a matrix in a static random access memory (hereinafter abbreviated as “SRAM”). The memory cell is formed by a flip-flop circuit and two access transistors AT1 and AT2.

The gates of the access transistors AT1 and AT2 are connected to the word line WL. The word line WL controls conduction of the access transistors AT1 and AT2.

In the flip-flop circuit, input terminals and output terminals of an inverter consisting of a load transistor LT1 and a driver transistor DT1 and another inverter consisting of a load transistor LT2 and a driver transistor DT2 are cross-coupled with each other thereby forming two storage nodes N1 and N2, for example.

A common gate electrode part 12b electrically connects the gates of the driver transistor DT1 and the load transistor LT1 with each other. Another common gate electrode part 12a electrically connects the gates of the driver transistor DT2 and the load transistor LT2 with each other.

The gate electrode part 12a extends to an element forming region formed with the load transistor LT1, and is electrically connected with the drain of the load transistor LT1 through a plug embedded in a prescribed shared contact hole SC.

The gate electrode part 12b is also electrically connected with the drain of the load transistor LT2 through a plug embedded in another prescribed shared contact hole SC.

When the voltage of one of the storage nodes N1 and N2 is at a high level, the voltage of the other one of the storage nodes N1 and N2 is at a low level, or vice versa. This state is referred to as a bistable state.

So far as a prescribed power supply voltage is applied to the memory cell, the memory cell can hold the bistable state. In the SRAM, a plurality of such memory cells are formed on the surface of a silicon substrate.

Operations of this memory cell are now briefly described. In order to write data in this memory cell, the access transistors AT1 and AT2 are rendered conductive through the word line WL corresponding to the memory cell, while a voltage is forcibly applied to a pair of complementary bit lines BL and /BL in response to a desired logical value.

Thus, the potentials of the two storage nodes N1 and N2 are set in the aforementioned bistable state in the flip-flop circuit, for holding data as the potential difference.

In order to read data, the access transistors AT1 and AT2 are rendered conductive thereby transmitting the potentials of the storage nodes N1 and N2 to the bit lines BL and /BL and reading the data.

The sectional structure of the memory cell of the SRAM is now described with reference to a section taken along the line III-III in FIG. 2. This portion includes a region formed with the shared contact hole SC.

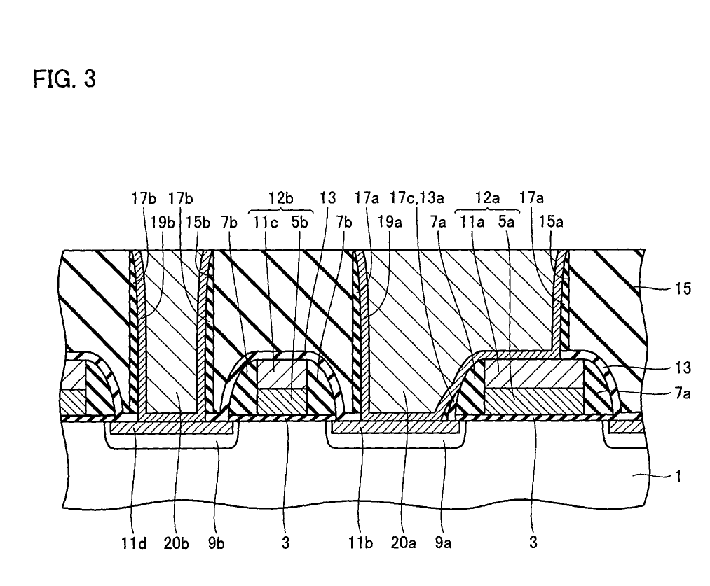

As shown in FIG. 3, the gate electrode parts 12a and 12b are formed on the surface of a semiconductor substrate 1 through gate insulator films 3. An impurity region 9b serving as a source region is formed on a region of the semiconductor substrate 1 located on one side of the gate electrode part 12b. Another impurity region 9a serving as a drain region is formed on another region of the semiconductor substrate 1 located on the other side of the gate electrode part 12b.

The gate electrode part 12b and the impurity regions 9a and 9b form the load transistor LT1. The gate electrode part 12b is connected with the gate of the driver transistor DT1 (see FIG. 2).

On the other hand, the gate electrode part 12a is connected with the gates of the load transistor LT2 and the driver transistor DT2 (see FIG. 2).

The gate electrode parts 12a and 12b have polysilicon films 5a and 5b and cobalt silicide films 11a and 11c formed on the polysilicon films 5a and 5b respectively. Other cobalt silicide films 11b and 11d are formed on the surfaces of the impurity regions 9a and 9b respectively.

Side wall insulator films 7a and 7b consisting of silicon nitride, for example, are formed on both side surfaces of the gate electrode parts 12a and 12b respectively. A further silicon nitride film 13 is formed to cover the gate electrode parts 12a and 12b and the side wall insulator films 7a and 7b.

An interlayer dielectric film 15 consisting of a silicon oxide film, for example, different in etching property from the silicon nitride film 13 is formed on the semiconductor substrate 1 to cover the gate electrode parts 12a and 12b.

The so-called shared contact hole 15a is formed in the interlayer dielectric film 15 to expose both of the upper surface of the gate electrode part 12a and the surface of the cobalt silicide film 11b.

A contact hole 15b is formed in the interlayer dielectric film 15 to expose the surface of the cobalt silicide film 11d.

Side wall nitride films 17a consisting of silicon nitride are formed on the side surfaces of the shared contact hole 15a. Side wall nitride films 17b consisting of silicon nitride are formed on the side surfaces of the contact hole 15b.

On a lower surface portion of one the side wall insulator films 7a located on the bottom of the shared contact hole 15a, a side wall nitride film 17c (and a side wall nitride film 13a) is further formed to cover the surface of a portion of a region of the semiconductor substrate 1 located under this side wall insulator film 7a.

A plug 20a is formed in the shared contact hole 15a through a barrier metal layer 19a interposed between the plug 20a and the side wall nitride films 17a and 17c. Another plug 20b is formed in the contact hole 15b through a barrier metal layer 19b interposed between the plug 20b and the side wall nitride films 17b.

The plugs 20a and 20b are electrically connected with prescribed wires (not shown) formed on the interlayer dielectric film 15, for forming the static memory cell shown in FIGS. 1 and 2.

A method of fabricating the semiconductor device comprising the aforementioned SRAM is now described. First, an element forming region for forming a prescribed element is formed on the main surface of the semiconductor substrate 1. An insulator film for defining the gate insulator films 3 is formed on the main surface of the semiconductor substrate 1.

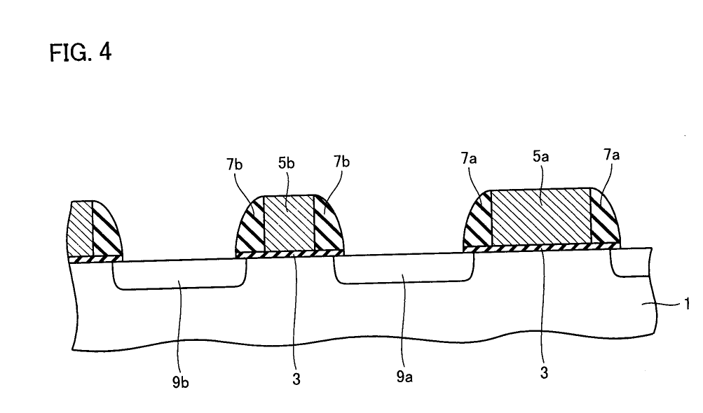

A polysilicon film for defining the gate electrode parts 12a and 12b is formed on the insulator film. Prescribed photolithography and working are performed on the polysilicon film thereby forming polysilicon films 5a and 5b partially defining the gate electrode parts 12a and 12b on the surface of the semiconductor substrate 1 through the gate insulator films 3, as shown in FIG. 4.

A silicon nitride film (not shown) having a thickness of about 40 to 60 nm (400 to 600 Å) is formed on the semiconductor substrate 1 to cover the polysilicon films 5a and 5b. This silicon nitride film is anisotropically etched thereby forming the side wall nitride films 7a and 7b on the side surfaces of the polysilicon films 5a and 5b respectively.

The polysilicon films 5a and 5b and the side wall nitride films 7a and 7b are employed as masks for implanting ions of an impurity having a prescribed conductivity type into the semiconductor substrate 1, thereby forming the impurity regions 9a and 9b.

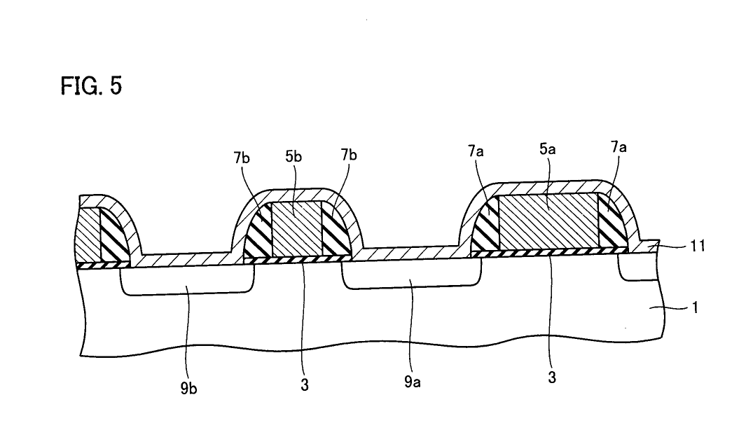

As shown in FIG. 5, a cobalt film 11 is formed on the semiconductor substrate 1 to cover the polysilicon films 5a and 5b. Proper heat treatment is performed thereby reacting silicon contained in the polysilicon films 5a and 5b as well as in the semiconductor substrate 1 with cobalt.

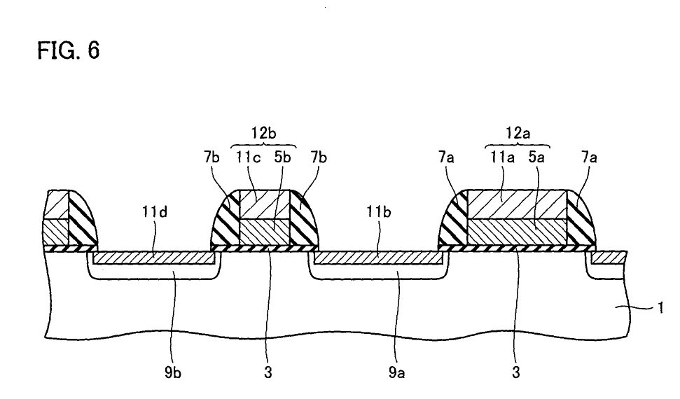

Thus, the cobalt silicide films 11a and 11c are formed on the polysilicon films 5a and 5b respectively thereby forming the gate electrode parts 12a and 12b having the polysilicon films 5a and 5b and the cobalt silicide films 11a and 11c respectively, as shown in FIG. 6.

The cobalt silicide films 11b and 11d are formed on the surfaces of the impurity regions 9a and 9b respectively. Thereafter unreacted portions of the cobalt film 11 are removed.

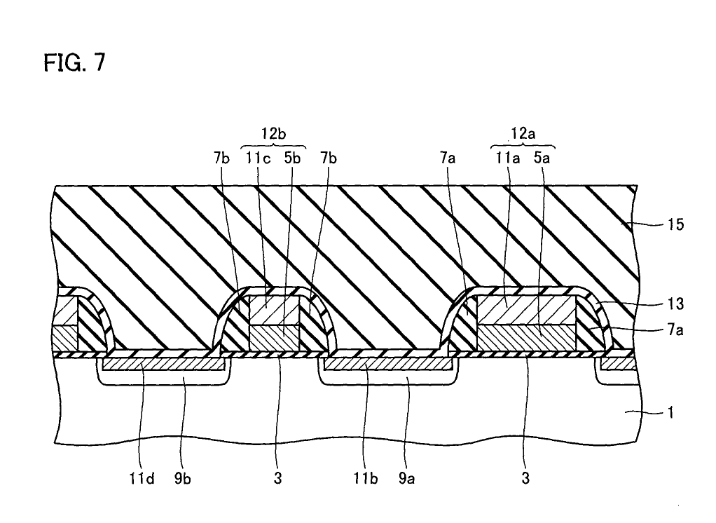

Then, the silicon nitride film 13 having a thickness of 20 to 50 nm (200 to 500 Å) is formed on the semiconductor substrate 1 to cover the gate electrode parts 12a and 12b, as shown in FIG. 7. The interlayer dielectric film 15 consisting of a silicon oxide film different in etching property from the silicon nitride film 13 is formed on the silicon nitride film 13.

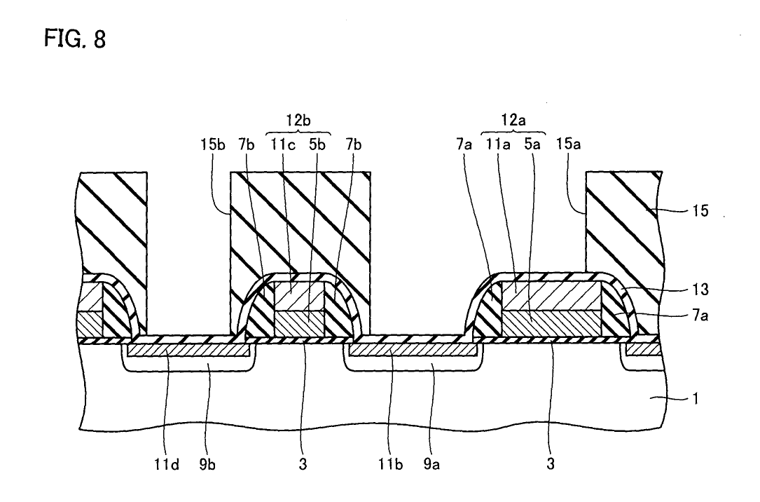

Prescribed photolithography and working are performed on the interlayer dielectric film 15, thereby forming the shared contact hole 15a in the interlayer dielectric film 15 to continuously expose the silicon nitride film 13 from a portion located on the upper surface of the gate electrode part 12 to a portion located on the cobalt silicide film 11b, as shown in FIG. 8.

The contact hole 15b exposing the portion of the silicon nitride film 13 located on the cobalt silicide film 11d is also formed in the interlayer dielectric film 15.

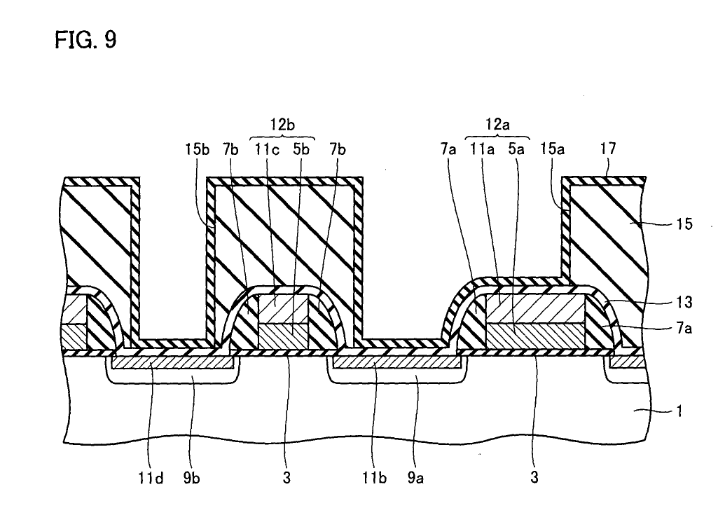

As shown in FIG. 9, a silicon nitride film 17 having a thickness of about 10 to 30 nm (100 to 300 Å), which is different in etching property from the silicon oxide film, is further formed on the interlayer dielectric film 15 including the inner surfaces of the shared contact hole 15a and the contact hole 15b under a condition not exceeding a temperature of about 600° C.

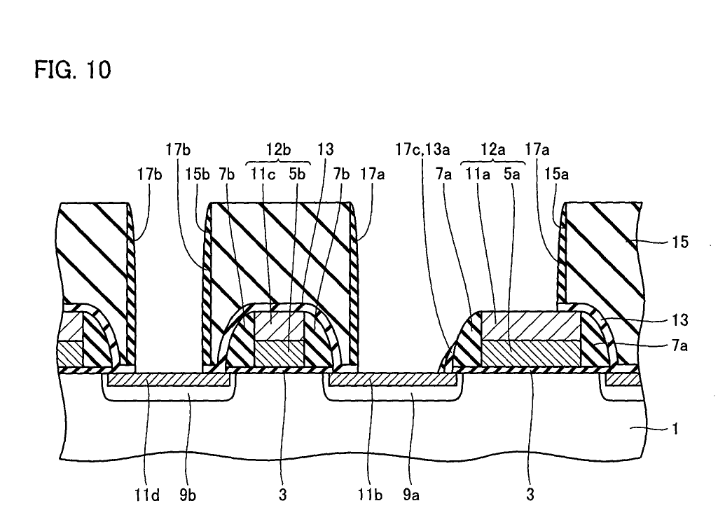

As shown in FIG. 10, the silicon nitride film 17 is anisotropically etched thereby forming the side wall nitride films 17a and 17b on the side surfaces of the shared contact hole 15a and the contact hole 15b respectively.

Further, the side wall nitride film 17c is formed on the surface of the lower portion of one of the side wall insulator films 7a to cover the surface of the portion of the region of the semiconductor substrate 1 located under this side wall insulator film 7a.

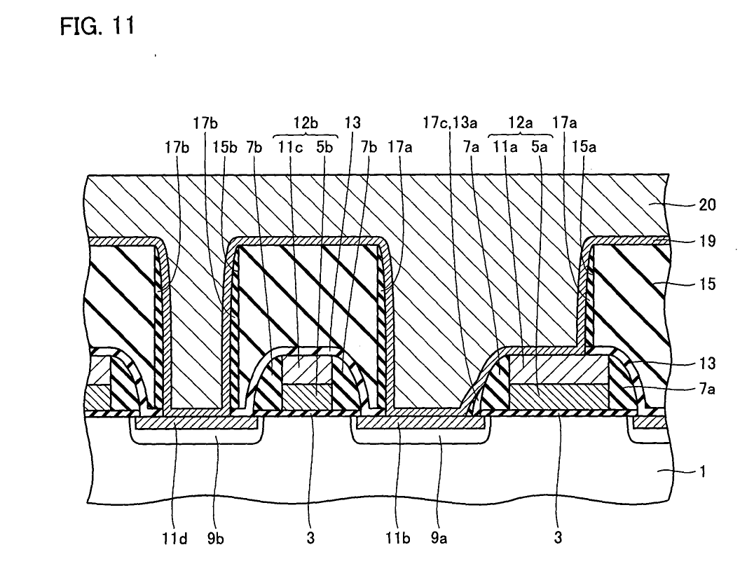

As shown in FIG. 11, a layer 19 for defining the barrier metal layers 19a and 19b is formed on the interlayer dielectric film 15 including the inner surfaces of the shared contact hole 15a and the contact hole 15b.

Then, a layer 20 for defining the plugs 20a and 20b is formed on the layer 19 for defining the barrier metal layers 19a and 19b, to fill up the shared contact hole 15a and the contact hole 15b.

Then, portions of the layer 20 for defining the plugs 20a and 20b and the layer 19 for defining the barrier metal layers 19a and 19b located on the upper surface of the interlayer dielectric film 15 are removed thereby forming the barrier metal layer 19a and the plug 20a in the shared contact hole 15a while forming the barrier metal layer 19b and the plug 20b in the contact hole 15b, as shown in FIG. 3.

Thereafter first and second metal wires (not shown) are formed on the interlayer dielectric film 15 to be electrically connected with the plugs 20a and 20b respectively.

The first metal wire is electrically connected with the gate electrode part 12a and the impurity region 9a through the plug 20a, while the second metal wire is connected with the impurity region 9b through the plug 20b. Thus, the primary portion of the semiconductor device comprising the SRAM is formed.

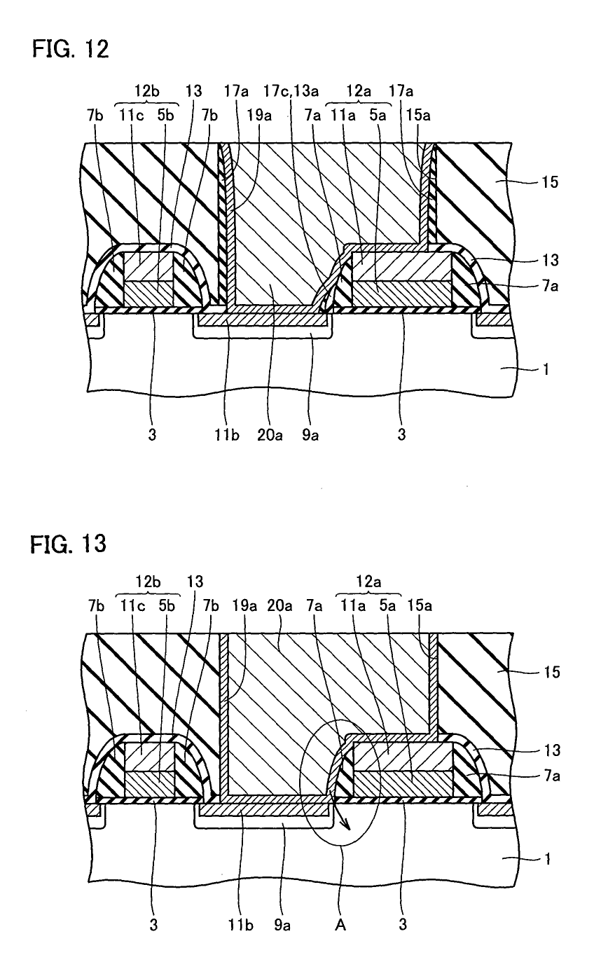

In the aforementioned semiconductor device, the side wall nitride film 17c (and the side wall nitride film 13a) is formed on the surface of the lower portion of one of the side wall insulator films 7a located on the shared contact hole 15a to cover the surface of the portion of the region of the semiconductor substrate 1 located under this side wall insulator film 7a, as shown in FIG. 12.

Even if the thickness of this side wall insulator film 7a is reduced due to etching for forming the shared contact hole 15a, therefore, a current can be inhibited from leaking from the plug 20a to the semiconductor substrate 1. This is now described.

When the shared contact hole 15a is formed in the interlayer dielectric film 15, portions of the silicon nitride film 13 located on the upper surface of the gate electrode part 12a and the cobalt silicide film 11b are removed by anisotropic etching.

If the anisotropic etching is excessively performed at this time, still another portion of the silicon nitride film 13 located on the surface of the side wall insulator film 7a may also be removed in particular. In addition, the side wall insulator film 7a may also be anisotropically etched.

Therefore, the thickness of the side wall insulator film 7a located on one of the side surfaces of the gate electrode part 12a, i.e., the length of the portion in contact with the semiconductor substrate 1, may be reduced as shown in FIG. 13, to partially expose the surface of the semiconductor substrate 1.

If the barrier metal layer 19a and the plug 20a are formed in the shared contact hole 15a in the aforementioned state, a current leaks from the plug 20a toward the semiconductor substrate 1 through a portion of the barrier metal layer 19a in contact with the exposed portion of the semiconductor substrate 1, as shown in a part A in FIG. 13.

In the aforementioned semiconductor device, however, the silicon nitride film 17 for defining the side wall nitride films 17a is formed in the shared contact hole 15a in the step shown in FIG. 9.

Even if the thickness of the side wall insulator film 7a is reduced due to the etching for forming the shared contact hole 15a in the step shown in FIG. 8 to partially expose the surface of the semiconductor substrate 1, therefore, the silicon nitride film 17 covers the exposed surface portion of the semiconductor substrate 1 in the step shown in FIG. 9.

Anisotropic etching is performed on the silicon nitride film 17 in the step shown in FIG. 10 thereby forming the side wall nitride films 17a and 17c etc. so that the side wall nitride film 17a covers the exposed surface portion in particular.

Consequently, the surface of the semiconductor substrate 1 is inhibited from exposure while the current is inhibited from leaking from the plug 20a toward the semiconductor substrate 1, as shown in FIG. 12.

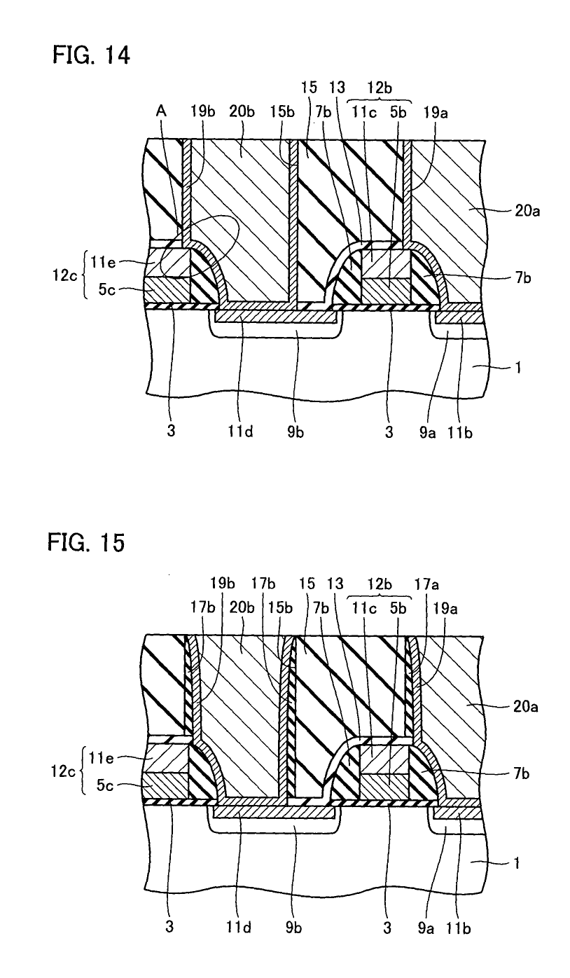

In the aforementioned semiconductor device, misregistration may be caused in formation of the contact hole 15b shown in FIG. 8 to expose the surfaces of the cobalt silicide films 11c and 11e in the gate electrode parts 12b and 12c as shown in FIG. 14, for example.

Also in this case, the silicon nitride film 17 formed in the step shown in FIG. 9 covers the exposed portions of the cobalt silicide films 11c and 11e, as shown in FIG. 15.

Consequently, the current can be inhibited from leaking from the plugs 20a and 20b to the cobalt silicide films 11c and 11e.

Thus, the semiconductor device according to this embodiment suppressing a leakage current can ensure a stable operation of the SRAM.

While the semiconductor device according to this embodiment has been described with reference to a silicon oxide film and a silicon nitride film employed as insulator films different in etching property from each other, the materials for the insulator films are not restricted to silicon oxide and silicon nitride so far as the second insulator film is not substantially etched when the first insulator film is etched.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device having a static memory cell including:
a pair of driver transistors having gates and drains cross-coupled with each other;
a pair of access transistors having sources connected to said drains of said driver transistors respectively; and
a pair of load transistors having drains and gates connected to said drains of said driver transistors and said gates of said driver transistors respectively,
said semiconductor device comprising:
a first gate electrode part and a second gate electrode part formed at a space from each other across an element forming region formed on the main surface of a semiconductor substrate;
a first impurity region of a prescribed conductivity type formed on a portion of said element forming region held between said first gate electrode part and said second gate electrode part;
a second impurity region of said prescribed conductivity type formed on another potion of said element forming region located opposite to the side provided with said second gate electrode part with respect to said first gate electrode part;
an interlayer dielectric film formed on said semiconductor substrate to cover said first gate electrode part and said second gate electrode part;
a first opening formed in said interlayer dielectric film to continuously expose the upper surface of said second gate electrode part and the surface of said first impurity region;
a first gate side wall insulator film formed on the side surface of said second gate electrode part;
a first opening side wall insulator film formed on the side surface of said first opening;
a second gate side wall insulator film formed on the surface of said first side wall insulator film to cover the surface of a portion of a region of said semiconductor substrate located under said first gate side wall insulator film; and
a first conductor part formed to fill up said first opening for electrically connecting said first impurity region and said second gate electrode part with each other, wherein
the first one of said pair of load transistors includes said first gate electrode part, said first impurity region and said second impurity region, and
said second gate electrode part forming the gate of the second one of said pair of load transistors and said first impurity region of said first load transistor are electrically connected with each other through said first conductor part.

2. The semiconductor device according to claim 1, wherein
said first gate side wall insulator film, said first opening side wall insulator film and said second gate side wall insulator film are different in etching property from said interlayer dielectric film.

3. The semiconductor device according to claim 2, wherein
said first gate side wall insulator film, said first opening side wall insulator film and said second gate side wall insulator film include silicon nitride films, and said interlayer dielectric film includes a silicon oxide film.

4. The semiconductor device according to claim 1, further comprising:
a second opening formed in said interlayer dielectric film to expose the surface of said second impurity region,
a second opening side wall insulator film formed on the side surface of said second opening, and
a second conductor part formed to fill up said second opening.

5. The semiconductor device according to claim 1, further comprising metal silicide layers formed on the surface of said first impurity region, the surface of-said second impurity region, the upper surface of said first gate electrode part and the upper surface of said second gate electrode part respectively.
